(19) United States
(12) Patent Application Publication
(10) Pub. No.: US 2005/0130437 A1
(43) Pub. Date: Jun. 16, 2005

(54) Dry film remove pre-filter system

(75) Inventors: Chih-Min Tseng, Hsin-Chu (TW); Chien-Hsun Peng, Hsin-Chu (TW); Szu-Yao Wang, Hsin-Chu (TW); Chun-Yen Lo, Hsin-Chu (TW)

Correspondence Address: STEPHEN B. ACKERMAN, 28 DAVIS AVENUE, POUGHKEEPSIE, NY, 12603, US

(73) Assignee: Taiwan Semiconductor Manufacturing Co.

(21) Appl. No.: 10/736,948

(22) Filed: Dec. 16, 2003

(51) Int. Cl. H01L 21/302; H01L 21/461

(52) U.S. Cl. 438/745

(57) ABSTRACT

In accordance with the objectives of the invention a new method and apparatus is provided for the removal of by-products resulting from a dry-film removal process. The conventional method and apparatus for controlling a dry-film removal process is extended by the addition of a Dry-Film Remove Pre-Filter System, which significantly enhances the capability of filtering a dry-film removal solution.

### BACKGROUND OF THE INVENTION

(1) Field of the Invention

The invention relates to the fabrication of integrated circuit devices, and more particularly, to a method and apparatus for improved dry-film removal as part of creating interconnect bumps over a substrate.

(2) Description of the Prior Art

Semiconductor devices are, after these devices have been created or as part thereof, provided with conductive interconnects which are frequently referred to as bumps or solder bumps.

A pattern of contact points is created over a substrate, as part of the creation of semiconductor devices in or over the substrate. This pattern of contact points serves to functionally connect the semiconductor devices to surrounding interconnect metal such as interconnect traces, solder bumps and the like.

The pattern for the contact points that are created over the substrate can be defined by a dry film, which is created over the substrate in dry form such as by laminating. The dry film is provided with a pattern of openings, which is the pattern of the contact points that are to be created over the substrate. A flowable material, such as solder, is then deposited over the substrate, which, due to the provided dry film, overlies and aligns with the pattern of contact points. After the flowable material has been deposited, a dry film is removed from the substrate in order to allow continued processing and packaging of the semiconductor die contained in the substrate.

The dry film is removed from the substrate by applying a solution having a chemical content to the surface of the substrate. Conventional methods do not adequately remove the by-products from the solution, imposing the need for frequent change of the solution in order to maintain a desired upper limit on the by-products that are allowed in the solution. The invention addresses this concern and provides a cost-effective method and apparatus for removing by-products that result from removing the dry film from the substrate.

U.S. Pat. No. 5,942,369 (Ota et al.) shows a positive photoresist composition.

U.S. Pat. No. 4,906,341 (Yamakawa et al.) shows a method and apparatus for manufacturing semiconductor devices.

### SUMMARY OF THE INVENTION

A principal objective of the invention is to remove by-products from a dry-film removal process in a cost-effective manner.

Another objective of the invention is to enhance filtering capabilities that are required for the removal of by-products that are created as a result of removing a dry-film from a substrate.

In accordance with the objectives of the invention a new method and apparatus is provided for the removal of by-products resulting from a dry-film removal process. The conventional method and apparatus for controlling a dry-film removal process is extended by the addition of a Dry Film Remove Pre-Filter System, which significantly enhances the capability of filtering a dry-film removal solution.

### BRIEF DESCRIPTION OF THE DRAWINGS

FIG. 1 shows a flow of the Dry Film Remove Pre-Filter System of the invention.

FIG. 2 shows a three dimensional view of the filter traps of the Pre-Filter Module.

FIG. 3 shows the Stripper Rate, the Trapping Rate and the Trap Port Size of the Dry Film Remove Pre-Filter System of the invention.

### DESCRIPTION OF THE PREFERRED EMBODIMENTS

A dry-film removal solution is conventionally contained in a dry-film solution reservoir. Conventional processes use a static tank in which the dry-film removal solution is contained. The method that is used to maintain the required chemical content of the dry-film removal solution is to replenish this solution as a function of processing time or as a function of expired time. The dry-film removal solution is conventionally disposed after removal from the static reservoir. The dry-film removal solution is conventionally not circulated and is not subjected to purification by any means.

The invention provides for the following new aspects of controlling the chemical content of dry-film removal solution:
the dry-film removal solution is circulated, and
the dry-film removal solution is filtered during the circulation there-of.

The providing these new aspects of controlling the chemical content of the dry-film removal solution, the invention:
extends the time period over which the dry-film solution can be used
reduces the residue content of the dry-film solution, and
improves control of the residue content of the dry-film solution.

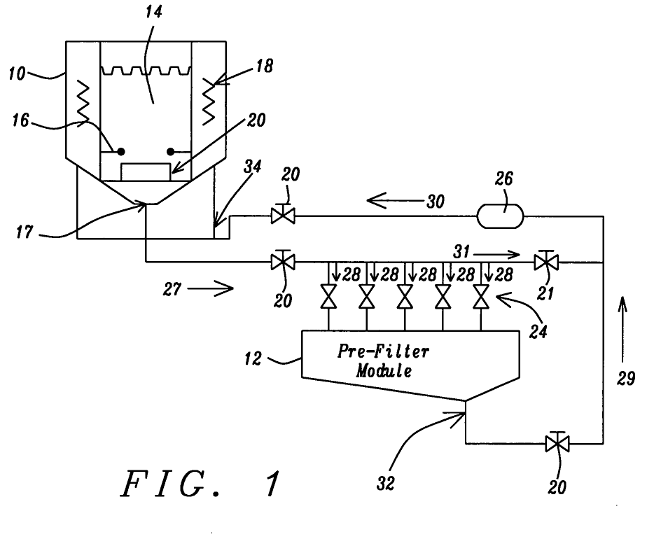

Referring now specifically to FIG. 1, there is shown the Dry Film Removal (DFR) Pre-Filter System of the invention wherein specifically are highlighted:
10, the dry-film solution reservoir of the system
12, the pre-filter module; contained within the cover unit 10 are:
14, the inner dry-film removal solution reservoir
16, the wafer support table; the wafer is not shown in FIG. 1
18, a heater element
20, an ultrasonic unit for exposure of the wafer that is contained on the wafer support table.

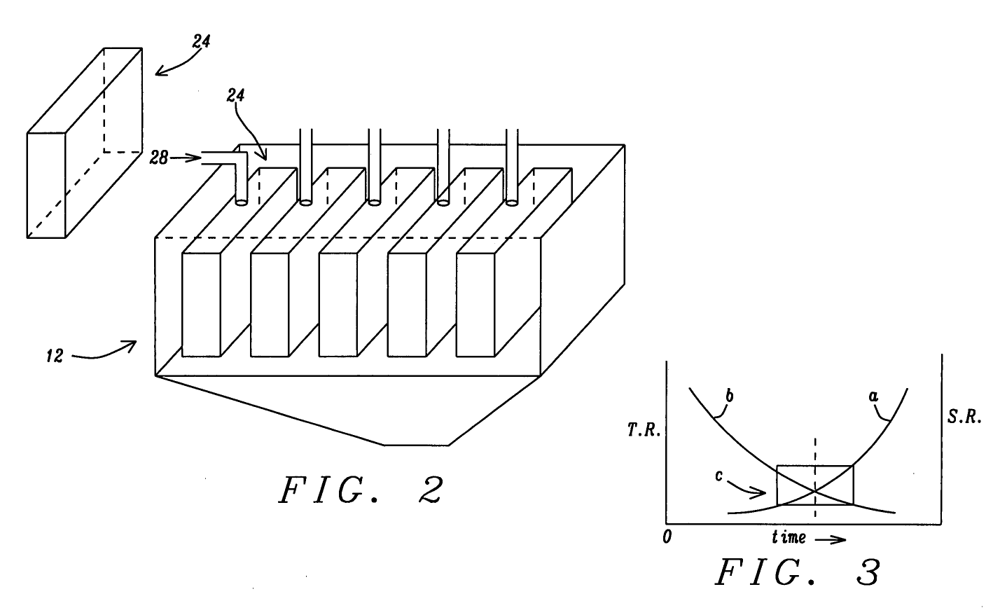

The dry-film removal solution that is contained in reservoir 10 exits, under the method and the apparatus of the invention, the reservoir 10 at exit port 17, creating dry-film removal solution flow 27. The dry-film removal solution flow 27 proceeds, following the indicated flow 28, through the pre-filter module 12 in which a number of traps 24 are arranged. This latter aspect of the invention is further explained using FIG. 2.

After the dry-film removal solution has passed through the pre-filter module 12, the dry-film removal solution exits the pre-filter module via exit port 32 of the pre-filter module 12 and continues as flow 29/30 after which the dry-film removal solution re-enters the reservoir 10 at entry port 34.

Further highlighted in FIG. 1 are control valves 20, which adjust the volume of the dry-film removal solution that is allowed to pass through the valves, thereby controlling the flows 27, 28, 29 and 30. Pump 26 establishes and maintains the flow of the dry-film removal solution through the highlighted DFR Pre-Filter System of the invention that is shown in diagram form in FIG. 1.

It is further clear that valve 21 can be used to adjust flow 31 of dry-film removal solution, thereby allowing for complete or partial by-passing of the Pre-Filter Module 12 by the dry-film removal solution.

The three-dimensional view of the traps 24, shown in FIG. 2, makes clear how the flow 28 of dry-film removal solution enters the Pre-Filter Module. The filtering action provided by the invention is enabled by passing the dry-film removal solution through the traps 24 whereby each of the traps 24 removes part of the dry-film removal solution contaminants from the dry-film solution, thus purifying the dry-film removal solution.

FIG. 3 highlights three key aspects of the method and apparatus of the invention.

The first of these three key aspects is the Strip Rate (S.R.), shown in curve “a” in FIG. 3, which is defined at the rate at which the dry-film is removed from the dry-film removal solution that passes through the Pre-Filter Module, in units of volume per time unit. The Strip Rate is observed to be directly proportional to the time that the dry-film removal solution passes through the Pre-filter Module and to the temperature of the dry-film removal solution at the time that this removal solution passes through the Pre-filter Module.

The second of these three key aspects is the Trap Rate (T.R.), shown as curve “b” in FIG. 3, which is defined at the rate at which the dry-film removal residue is trapped by the traps 24 in units of volume per time unit. The Trap Rate is observed to be inversely proportional to the time that is required for the dry-film removal solution to pass through the traps of the Pre-filter Module.

The third of these three key aspects is the Trap Port Size, shown as element “c” in FIG. 3, which is defined at the surface area of the traps 24 through which the dry-film removal solution passes for the removal of dry-film residue from the dry-film removal solution. It is clear from element “c” shown in FIG. 3 that a larger Trap port size results, as is to be expected, in increased value of dry-film residue being removed from the dry-film removal solution.

The following comments apply to the invention, these comments provide additional information relating to the invention and further clarify the above presented information:
the Dry Film Removal (DFR) pre-filter module 12 is not at all times part of the dry-film removal circulation loop
the by-products of the dry-film removal from the dry-film removal solution will be dissolved and returned to the solution, based on dry film and chemical characteristics of the dry-film and driven by the time of operation of the DFR system
every valve and pre-filter module, that is part of the DFR Pre-filter system, is provided with control capabilities such that these units can be adjusted, that is opened and or closed, as a function of the time that the system is functioning
the traps, which form part of the DFR Pre-filter system, will therefore not be permanently “soaked” in solution
by-products that are trapped are not returned to the solution
at the time that the pre-filter valve is closed, the circulation of the solution will proceed in a normal, that is conventional or prior art, loop
the functioning of the DFR Pre-filter system is based on the Stripping Rate (S.R.) and the Trapping Rate (T.R.), as shown in the graphic presentation of FIG. 3
experiments and observations have indicated that dry-film will mostly be stripped up to 5 minutes into the circulation time of the solution, it has further been observed that the dry-film will essentially dissolve in the solution after the circulation time of the solution exceeds 15 minutes; from this it must be concluded that trapping of dry-film can only be effective up to about 15 minutes after the dry-film has been added to the solution
a frequently used chemical composition of the dry-film removal solution comprises SPS-200(DMSO) at a processing temperature of about 60 degrees C., or KOH; the chemical composition of SPS-200 is thereby understood to be 92% DMSO and 2% TMAM
the operational temperature of the DFR Pre-filter system is constant; an optimum operational temperature is established with the objective of achieving optimum Stripping Rate, this aspect of the invention is a key aspect
the DFR Pre-filter system is preferably applied to solder bump processes
a typical flow-rate of the dry-film solution is about 20 liter/minute (LPM)
the control valves that are part of the DFR Pre-filter system are controlled and adjusted in an inter-dependent manner; for instance valve 21 will be used when purposes of maintenance, for flow by-pass and for normal return
the DFR Pre-filter system can be used in a permanent or in-interrupted mode, meaning that the dry-film solution is not replaced if the DFR Pre-filter system is functional
it is an option to replace the solution, which results in improving the effectiveness of the solution in removing dry-film there-from
the T.R and S.R parameters are affected by a large number of environmental and processing parameters and do not readily lend themselves to understanding or explanation
a preferred trap design calls for a size of the trap port, which is the entry point of the dry-film removal solution into the trap, of about 100 mm×120 mm, with the trap having a preferred height of about 150 mm, and
the sloping part of element 10, as shown in FIG. 1, is designed such that the sloping prevents the accumulation of by-product on the bottom of the tank 10.

Although the invention has been described and illustrated with reference to specific illustrative embodiments thereof, it is not intended that the invention be limited to those illustrative embodiments. Those skilled in the art will recognize that variations and modifications can be made without departing from the spirit of the invention. It is therefore intended to include within the invention all such variations and modifications which fall within the scope of the appended claims and equivalents thereof.

1. A method of removing dry-film contaminants from a dry-film solution, comprising:
first applying a dry-film removal solution to a semiconductor wafer to remove a dry-film from the semiconductor wafer, said dry-film removal solution containing dry-film;
circulating said dry-film removal solution;
collecting said circulated dry-film removal solution;
pre-filtering said dry-film removal solution, thereby removing said dry-film from said collected dry-film removal solution; and
second applying a dry-film removal solution to said at least one semiconductor wafer.

2. The method of claim 1, wherein said circulating said dry-film removal solution comprises providing means for circulating said dry-film removal solution from said first applying to said collecting to said pre-filtering to said second applying a dry-film removal solution, further providing at least one fluid control valve with interconnecting tubing for flow of dry-film removal solution there-through and at least one pump for propulsion of dry-film removal solution there-through.

3. The method of claim 1, said pre-filtering being intermittently applied with time-periods between successive applications, assuring that the pre-filtering is not at all times part of a dry-film removal circulation loop.

4. The method of claim 1, whereby by-products of the dry-film pre-filtering from the dry-film removal solution will be dissolved and returned to the solution.

5. The method of claim 4, whereby said dissolving and returning to the solution of said by-products is dependent on the time of operation of the dry-film pre-filtering.

6. The method of claim 1, said pre-filtering comprising valves and a pre-filter module.

7. The method of claim 6, said valves and a pre-filter module comprising control capabilities such that said valves and pre-filter module can be adjusted as a function of the time of operation of the pre-filter module.

8. The method of claim 1, said pre-filter comprising traps, whereby said dry-film removal solution not being permanently embedded in said traps.

9. The method of claim 1, whereby by-products that are pre-filtered are not returned to the dry-film removal solution.

10. The method of claim 1, further providing for conventional circulation of the dry-film removal solution by closing a pre-filter valve.

11. The method of claim 1, whereby effectiveness of said pre-filtering is dependent on a Stripping Rate and Trapping Rate of the dry-film removal solution.

12. The method of claim 1, said pre-filtering preferably being applied for a period of between about 5 minutes and 15 minutes after initiation of said circulating of the dry-film removal solution.

13. The method of claim 1, wherein said dry-film removal solution comprises SPS-200(DMSO) or KOH, applied at a processing temperature of about 60 degrees C., whereby a chemical composition of SPS-200 is 92% DMSO and 2% TMAM.

14. The method of claim 1, whereby an operational temperature of the pre-filtering is constant.

15. The method of claim 1, wherein an optimum operational temperature is established with as objective of achieving an optimum Stripping Rate.

16. The method of claim 1, whereby pre-filtering is preferably applied to solder bump processes.

17. The method of claim 1, wherein a preferred flow-rate of the dry-film removal solution is about 20 liter/minute (LPM).

18. The method of claim 1, said pre-filtering comprising control valves, said control valves being controlled in an inter-dependent manner.

19. The method of claim 18, wherein said control valves are applied for purposes of maintenance and of flow by-pass of dry-film removal solution and for normal return of dry-film removal solution.

20. The method of claim 1, wherein said dry-film solution is not replaced during said pre-filtering.

21. The method of claim 1, wherein said dry-film solution is replaced during said pre-filtering, resulting in improving effectiveness in removing dry-film from the dry-film solution.

22. The method of claim 1, said pre-filtering comprising at least one trap for filtering of said dry-film removal solution, said trap comprising a structure having square or rectangular sides.

23. The method of claim 22, wherein said at least one trap has an entry port, said entry port having dimensions of about 100 mm×120 mm, said trap having a preferred height of about 150 mm.

24. An apparatus for removing dry-film contaminants from a dry-film solution, comprising:
a means for first applying a dry-film removal solution to a semiconductor wafer to remove a dry-film from the semiconductor wafer, said dry-film removal solution containing dry-film;
a means for circulating said dry-film removal solution;
a means for collecting said circulated dry-film removal solution;
a means for pre-filtering said dry-film removal solution, thereby removing said dry-film from said collected dry-film removal solution; and
a means for second applying a dry-film removal solution to said at least one semiconductor wafer.

25. The apparatus of claim 24, wherein said means for circulating said dry-film removal solution comprises providing means for circulating said dry-film removal solution from said first applying to said collecting to said pre-filtering to said second applying a dry-film removal solution, further providing at least one fluid control valve with interconnecting tubing for flow of dry-film removal solution there-through and at least one pump for propulsion of dry-film removal solution there-through.

26. The apparatus of claim 24, said means for pre-filtering being intermittently applied with time-periods between successive applications, assuring that the pre-filtering is not at all times part of a dry-film removal circulation loop.

27. The apparatus of claim 24, whereby by-products of the dry-film pre-filtering from the dry-film removal solution will be dissolved and returned to the solution.

28. The apparatus of claim 27, whereby said dissolving and returning to the solution of said by-products is dependent on the time of operation of the means for dry-film pre-filtering.

29. The apparatus of claim 24, said means for pre-filtering comprising valves and a pre-filter module.

30. The apparatus of claim 29, said valves and a pre-filter module comprising control capabilities such that said valves and pre-filter module can be adjusted as a function of the time of operation of the means for pre-filtering.

31. The apparatus of claim 24, said means for pre-filtering comprising traps, said dry-film removal solution not being permanently embedded in said traps.

32. The apparatus of claim 24, whereby by-products that are pre-filtered are not returned to the dry-film removal solution.

33. The apparatus of claim 24, further comprising means for circulation of the dry-film removal solution by closing a pre-filter valve.

34. The apparatus of claim 24, whereby effectiveness of said means for pre-filtering is dependent on a Stripping Rate and Trapping Rate of the dry-film removal solution.

35. The apparatus of claim 24, said means for pre-filtering preferably being applied for a period of between about 5 minutes and 15 minutes after initiation of said circulating of the dry-film removal solution.

36. The apparatus of claim 24, wherein said dry-film removal solution comprises SPS-200(DMSO) or KOH, applied at a processing temperature of about 60 degrees C., whereby a chemical composition of SPS-200 is 92% DMSO and 2% TMAM.

37. The apparatus of claim 24, whereby an operational temperature of the means of pre-filtering is constant.

38. The apparatus of claim 24, wherein an optimum operational temperature is established with as objective of achieving an optimum Stripping Rate.

39. The apparatus of claim 24, whereby said means for pre-filtering is preferably applied to solder bump processes.

40. The apparatus of claim 24, wherein a preferred flow-rate of the dry-film removal solution is about 20 liter/minute (LPM).

41. The apparatus of claim 24, said means for pre-filtering comprising control valves, said control valves being controlled in an inter-dependent manner.

42. The apparatus of claim 41, wherein said control valves are applied for purposes of maintenance and of flow by-pass of dry-film removal solution and for normal return of dry-film removal solution.

43. The apparatus of claim 24, wherein said dry-film solution is not replaced during said pre-filtering.

44. The apparatus of claim 24, wherein said dry-film solution is replaced during said pre-filtering, resulting in improving effectiveness in removing dry-film from the dry-film solution.

45. The apparatus of claim 24, said means for pre-filtering comprising at least one trap for filtering of said dry-film removal solution, said trap comprising a structure having square or rectangular sides.

46. The apparatus of claim 45, wherein said at least one trap has an entry port, said entry port having dimensions of about 100 mm×120 mm, said trap having a preferred height of about 150 mm.

47. An apparatus for removing dry-film contaminants from a dry-film solution, comprising:
first applying a dry-film removal solution to a semiconductor wafer to remove a dry-film from the semiconductor wafer, said dry-film removal solution containing dry-film;
circulating said dry-film removal solution;
collecting said circulated dry-film removal solution;
pre-filtering said dry-film removal solution, thereby removing said dry-film from said collected dry-film removal solution; and
second applying a dry-film removal solution to said at least one semiconductor wafer.

48. The apparatus of claim 47, wherein said circulating said dry-film removal solution comprises providing means for circulating said dry-film removal solution from said first applying to said collecting to said pre-filtering to said second applying a dry-film removal solution, further providing at least one fluid control valve with interconnecting tubing for flow of dry-film removal solution there-through and at least one pump for propulsion of dry-film removal solution there-through.

49. The apparatus of claim 47, said pre-filtering being intermittently applied with time-periods between successive applications, assuring that the pre-filtering is not at all times part of a dry-film removal circulation loop.

50. The apparatus of claim 47, whereby by-products of the dry-film pre-filtering from the dry-film removal solution will be dissolved and returned to the solution.

51. The apparatus of claim 50, whereby said dissolving and returning to the solution of said by-products is dependent on the time of operation of the means for dry-film pre-filtering.

52. The apparatus of claim 47, said pre-filtering comprising valves and a pre-filter module.

53. The apparatus of claim 52, said valves and a pre-filter module comprising control capabilities such that said valves and pre-filter module can be adjusted as a function of the time of operation of the means for pre-filtering.

54. The apparatus of claim 47, said pre-filtering comprising traps, said dry-film removal solution not being permanently embedded in said traps.

55. The apparatus of claim 47, whereby by-products that are pre-filtered are not returned to the dry-film removal solution.

56. The apparatus of claim 47, further comprising circulation of the dry-film removal solution by closing a pre-filter valve.

57. The apparatus of claim 47, whereby effectiveness of said means for pre-filtering is dependent on a Stripping Rate and Trapping Rate of the dry-film removal solution.

58. The apparatus of claim 47, said pre-filtering preferably being applied for a period of between about 5 minutes and 15 minutes after initiation of said circulating of the dry-film removal solution.

59. The apparatus of claim 47, wherein said dry-film removal solution comprises SPS-200(DMSO) or KOH, applied at a processing temperature of about 60 degrees C., whereby a chemical composition of SPS-200 is 92% DMSO and 2% TMAM.

60. The apparatus of claim 47, whereby an operational temperature of pre-filtering is constant.

61. The apparatus of claim 47, wherein an optimum operational temperature is established with as objective of achieving an optimum Stripping Rate.

62. The apparatus of claim 47, whereby said pre-filtering is preferably applied to solder bump processes.

63. The apparatus of claim 47, wherein a preferred flow-rate of the dry-film removal solution is about 20 liter/minute (LPM).

64. The apparatus of claim 47, said pre-filtering comprising control valves, said control valves being controlled in an inter-dependent manner.

65. The apparatus of claim 64, wherein said control valves are applied for purposes of maintenance and of flow by-pass of dry-film removal solution and for normal return of dry-film removal solution.

66. The apparatus of claim 47, wherein said dry-film solution is not replaced during said pre-filtering.

67. The apparatus of claim 47, wherein said dry-film solution is replaced during said pre-filtering, resulting in improving effectiveness in removing dry-film from the dry-film solution.

68. The apparatus of claim 47, said pre-filtering comprising at least one trap for filtering of said dry-film removal solution, said trap comprising a structure having square or rectangular sides.

69. The apparatus of claim 68, wherein said at least one trap has an entry port, said entry port having dimensions of about 100 mm×120 mm, said trap having a preferred height of about 150 mm.
